(19) United States
(12) Patent Application Publication
(10) Pub. No.: US 2005/0062138 A1
(43) Pub. Date: Mar. 24, 2005

(54) Semiconductor structure with electrically isolated sidewall electrodes and method for fabricating the structure

(76) Inventor: Kirt Reed Williams, Portola Valley, CA (US)

Correspondence Address: AGILENT TECHNOLOGIES, INC.;Intellectual Property Administration, Legal Department, DL429, P.O. Box 7599, Loveland, CO, 80537-0599, US

(21) Appl. No.: 10/668,136

(22) Filed: Sep. 22, 2003

(51) Int. Cl. H01L 29/40

(52) U.S. Cl. 257/664

(57) ABSTRACT

A semiconductor structure with electrically isolated sidewall electrodes on one or more sides of the structure and a method for fabricating the structure are disclosed. The electrically isolated sidewall electrodes are composed of silicon-based conductive material, e.g., doped polysilicon, which allows the electrodes to be formed on one or more sides of the semiconductor structure by using stop-on-oxide deep reactive-ion etching (DRIE). The electrically isolated sidewall electrodes allow the semiconductor structure to generate electrostatic forces between a side surface of the semiconductor structure and a side surface of a similar semiconductor structure. Thus, the semiconductor structure may be used as a part of an electrostatic actuator in a microelectromechanical system (MEMS) device.

### FIELD OF THE INVENTION

The invention relates generally to semiconductor structures, and more particularly to a semiconductor structure with electrically isolated electrodes.

### BACKGROUND OF THE INVENTION

Various microelectromechanical system (MEMS) devices use electrostatic actuators to move desired elements. As an example, MEMS optical cross-connect switches may use electrostatic actuators to displace or pivot micro-mirrors to selectively reflect optical signals to desired paths. Many electrostatic actuators are fabricated from semiconductor substrates, which allows circuitry to be fabricated along with the electrostatic actuators. The circuitry may be used to drive the electrostatic actuators or to perform other electrical functions.

Although there are different types of electrostatic actuators that can be used in MEMS devices, such as MEMS optical cross-connect switches, comb-drive actuators are currently widely used in MEMS devices. A comb-drive actuator comprises a stationary structure, or a “stator,” and a displaceable structure, or a “mover,” which are made from semiconductor substrates. The mover is supported by flexures, which allows the mover to be displaced with respect to the stator. The stator and mover of the comb-drive actuator resemble combs, and hence, the name “comb-drive actuator”. The stator and mover both include fingers that are interdigitated with each other. When a voltage difference is applied to the stator and the mover, an electrostatic force is created due to an electric field generated between the interdigitated fingers of the stator and mover, which causes the mover to be displaced toward the stator. The motion provided by the displaced mover can be used, for example, to pivot a micro-mirror.

A shortcoming of the comb-drive actuators is that actuators provide motion in only one direction. That is, a mover of a comb-drive actuator can only be displaced toward the stator since the generated electric field can only cause an attractive force between the mover and the stator.

Another shortcoming of the comb-drive actuators is that accurate positioning of a mover with respect to the corresponding stator is difficult since a precise voltage difference applied between the mover and the stator is needed to accurately position the mover with respect to the stator. In addition, the flexure springs supporting the mover must be fabricated with a precise spring constant so that accurate positioning of the mover can be achieved.

An electrostatic actuator, which can potentially alleviate the described shortcomings of the comb-drive actuators, is described in U.S. Pat. No. 6,362,556 issued to Hoen. Similar to a comb-drive actuator, the electrostatic actuator of Hoen includes a stationary semiconductor member and a movable semiconductor member. However, the stationary member is positioned above and parallel to the movable member. On the opposing surfaces, the stationary and movable members include a number of parallel drive electrodes, which can generate electrostatic forces between the drive electrodes of the stationary and movable members when voltages are selectively applied to the drive electrodes. The generated electrostatic forces can then be modified by reconfiguring the voltages applied to the drive electrodes to laterally displace the movable member with respect to the stationary member in a controlled manner. The lateral displacement of the movable member is used to pivot a reflector for optical switching.

As described above, the electrostatic actuator of Hoen uses parallel electrodes fabricated on the opposed surfaces of the stationary and movable semiconductor members. However, other potential designs of electrostatic actuators may need stationary and/or movable semiconductor members that include parallel electrodes on side surfaces.

Therefore, what is needed is a semiconductor structure with electrically isolated electrodes on one or more side surfaces of the structure and a method for fabricating the semiconductor structure.

### SUMMARY OF THE INVENTION

A semiconductor structure with electrically isolated sidewall electrodes on one or more sides of the structure and a method for fabricating the structure are disclosed. The electrically isolated sidewall electrodes are composed of silicon-based conductive material, e.g., doped polysilicon, which allows the electrodes to be formed on one or more sides of the semiconductor structure by using a stop-on-oxide deep reactive-ion etching (DRIE). The electrically isolated sidewall electrodes allow the semiconductor structure to generate electrostatic forces between a side surface of the semiconductor structure and a side surface of a similar semiconductor structure. Thus, the semiconductor structure may be used as a part of an electrostatic actuator in a microelectromechanical system (MEMS) device.

A semiconductor structure in accordance with an embodiment of the invention includes a semiconductor core having a major surface and a side surface, which are orthogonal to each other. The semiconductor structure further includes a layer of insulating material, such as an oxide, on the side surface of the semiconductor core and a number of electrically isolated electrodes arrayed along the layer of insulating material. The electrically isolated electrodes may be arranged such that the electrodes extend substantially in a direction orthogonal to the major surface of the semiconductor core. The electrically isolated electrodes may include conductive material having etch selectivity with respect to the insulating material. The conductive material may be silicon-based conductive material, such as doped polysilicon.

A method for fabricating a semiconductor structure in accordance with an embodiment of the invention includes providing a semiconductor core with a side surface, forming a layer of insulating material on the side surface of the semiconductor core, forming a layer of conductive material adjacent to the layer of insulating material, and selectively etching the layer of conductive material using a stop-on-oxide deep reactive ion etching to define electrically isolated electrodes arrayed along the layer of insulating material on the side surface of the semiconductor core.

Other aspects and advantages of the present invention will become apparent from the following detailed description, taken in conjunction with the accompanying drawings, illustrated by way of example of the principles of the invention.

### BRIEF DESCRIPTION OF THE DRAWINGS

FIG. 1 is a perspective view of a portion of a semiconductor structure with electrically isolated sidewall electrodes in accordance with an embodiment of the present invention.

FIG. 2 is a side view of the semiconductor structure in FIG. 1.

FIG. 3 is a top view of the semiconductor structure in FIG. 1.

FIG. 4 is a perspective view of a portion of a semiconductor structure with electrically isolated sidewall electrodes in accordance with an embodiment of the invention.

FIG. 5 is a perspective view of an electrostatic actuator, which may include one or more semiconductor structures in accordance with an embodiment of the invention.

FIG. 6 is a flow diagram of a process of fabricating the semiconductor structure of FIG. 1.

FIGS. 7-22 illustrate various stages during the fabrication of the semiconductor structure of FIG. 1.

FIG. 23 is a flow diagram of a method for fabricating a semiconductor structure with electrically isolated sidewall electrodes in accordance with an embodiment of the invention.

### DETAILED DESCRIPTION

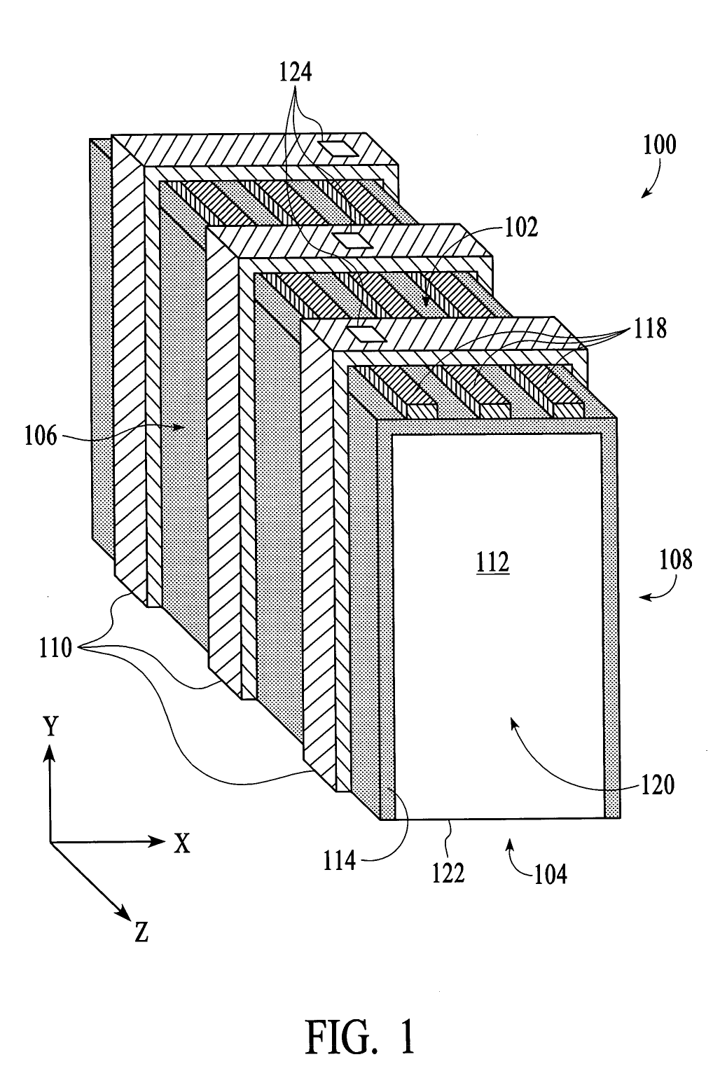

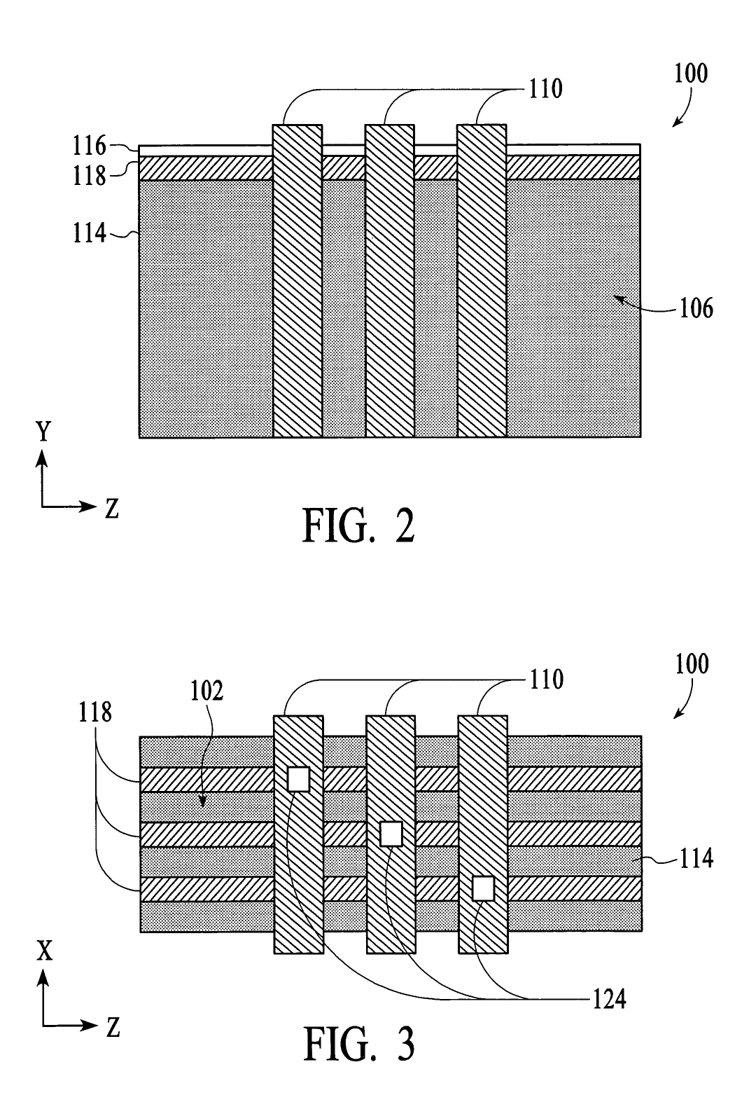

With reference to FIGS. 1, 2 and 3, a portion of a semiconductor structure 100 in accordance with an embodiment of the invention is shown. FIG. 1 is a perspective view of the semiconductor structure 100, while FIGS. 2 and 3 are side and top views of the structure, respectively. The semiconductor structure 100 has a top surface 102, a bottom surface 104 and side surfaces 106 and 108. As shown in FIGS. 1 and 2, the semiconductor structure 100 includes electrically isolated sidewall electrodes 110 on the side surfaces 106 and 108 of the structure. The electrically isolated sidewall electrodes 110 may be used to generate electrostatic forces between a side surface of the structure and a side surface of another similar semiconductor structure with electrically isolated sidewall electrodes. Thus, the semiconductor structure 100 may be used as a part of an electrostatic actuator in a microelectromechanical system (MEMS) device. As an example, the semiconductor structure 100 may be used as a stationary member of an electrostatic actuator, i.e., a stator, or a movable member of the actuator, i.e., a mover. However, the semiconductor structure may be used in other electrical devices in which electrically isolated sidewall electrodes are needed.

The semiconductor structure 100 includes a semiconductor core 112, insulating layers 114 and 116 (the insulating layer 116 is only shown in FIG. 2), interconnects 118 and the electrically isolated electrodes 110. The semiconductor core 112 may be defined from a silicon wafer, which allows the use of at least some conventional semiconductor processing techniques to fabricate the semiconductor structure 100. In some embodiments, the semiconductor core 112 may defined from a single-crystal silicon wafer, which has structural properties that are suitable for performing mechanical operations used in miniature mechanical devices such as those used for providing lateral motion for a MEMS device. As described below, the semiconductor core 112 is typically part of a bonded wafer pair. A bonded wafer pair is defined herein as a thin silicon device wafer that is bonded to a thicker silicon handle wafer. As an example, the device wafer may be about 30 μm thick and the handle wafer may be about 525 μm thick. The semiconductor core 112 is the foundation of the semiconductor structure 100. Thus, the semiconductor structure 100 conforms to the shape of the semiconductor core 112. Consequently, the top, bottom, and side surfaces 102, 104, 106 and 108 of the semiconductor structure 100 correspond to the surfaces of the semiconductor core 112. The top and bottom surfaces 102 and 104 of the semiconductor structure 100 correspond to the top and bottom surfaces of the semiconductor core 112. Similarly, the side surfaces 106 and 108 of the semiconductor structure 100 correspond to side surfaces of the semiconductor core 112. As used herein, the top surface of the semiconductor core 112 refers to one of two flat major surfaces of a silicon wafer from which the semiconductor core is derived. Thus, the top surface of the semiconductor core 112 is sometimes referred to herein as the major surface. In FIG. 1, the major or top surface of the semiconductor core 112 is parallel to a plane defined by the X and Z-axes. In addition, the side surfaces of the semiconductor core 112 refer to surfaces orthogonal to the major surface of the semiconductor core. Furthermore, as used herein, the term “horizontal” refers to a direction parallel to the major surface of the semiconductor core 112, and the term “vertical” refers to a direction parallel the side surfaces of the semiconductor core even though the orientations of the major and side surfaces of the semiconductor core may differ from the horizontal and vertical, respectively, if the spatial orientation of the semiconductor core is changed from that shown.

The insulating layer 114 of the semiconductor structure 100 is formed on the semiconductor core 112 on the top surface of the core and on the two side surfaces of the core that correspond to the side surfaces 106 and 108 of the structure. The insulating layer 114 may also be on the front side surface 120 of the semiconductor core 112, which is shown to be exposed in FIG. 1. The insulating layer 114 provides electrical insulation between the semiconductor core 112 and the electrically isolated electrodes 110, as well as electrical insulation between the semiconductor core and the interconnects 118. The insulating layer 114 is composed of a dielectric material, which is preferably conformal, such as an oxide, so that all the exposed surfaces, excluding the bottom surface 122, of the semiconductor core 112 are completely coated with the dielectric material.

The interconnects 118 of the semiconductor structure 100 are formed on the insulating layer 114 on the top surface of the semiconductor core 112. The interconnects 118 may be composed of any electrically conductive material, such as polysilicon, that is compatible with the subsequent processing. As shown in FIGS. 1, 2 and 3, the interconnects 118 extend along the length of the semiconductor structure 100, which coincides with the Z-axis. In the illustrated embodiment, the interconnects 118 are electrically connected to different electrically isolated electrodes 110, as indicated by electrical connections 124, such that each interconnect is electrically connected to a different one of the electrodes. However, in other embodiments, each interconnect 118 may be electrically connected to two or more electrically isolated electrodes 110, or each electrode may be electrically connected to two or more interconnects. The interconnects 118 allow voltages to be selectively applied to the electrically isolated electrodes 110. The voltages applied to the electrically isolated electrodes 110 can create electrostatic forces between a side surface of the semiconductor structure 100 and a side surface of another similar semiconductor structure.

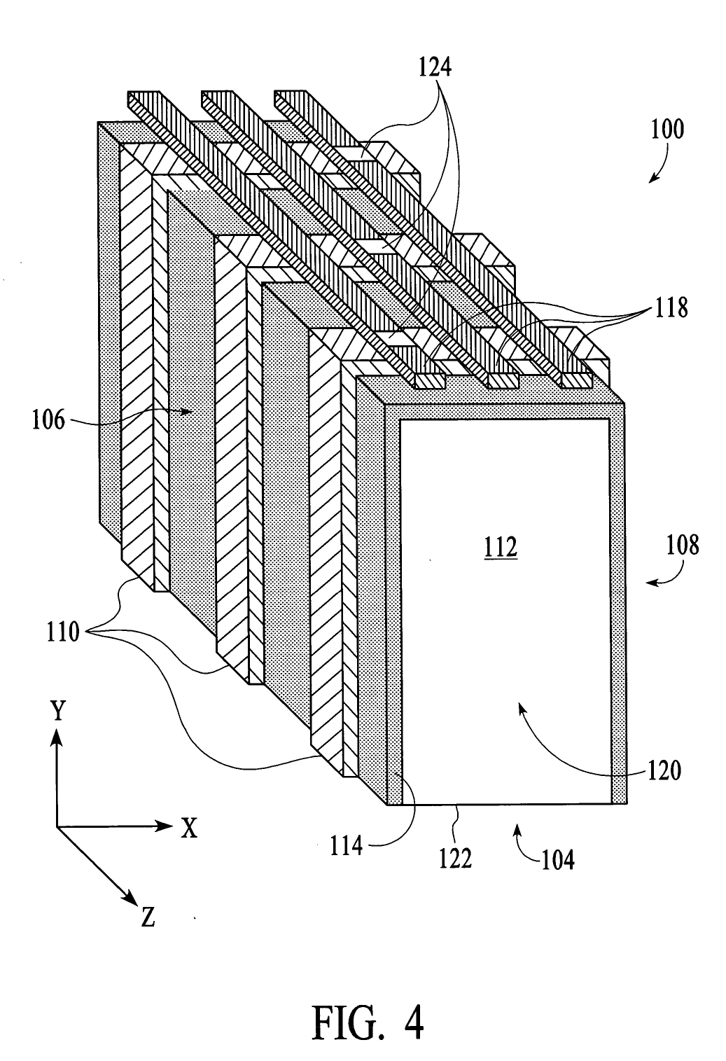

As stated above, the electrically isolated electrodes 110 of the semiconductor structure 100 are located at the side surfaces 106 and 108 of the semiconductor structure. In addition, the electrodes 110 are formed over the interconnects 118 on the top surface 102 of the semiconductor structure. Specifically, the electrodes 110 are formed on the insulating layer 114 on the side surfaces 106 and 108 of the semiconductor structure 100 and on the insulating layer 116 over the interconnects 118 on the top surface 102 of the semiconductor structure, as illustrated in FIG. 2. Similar to the insulating layer 114, the insulating layer 116 is made of a dielectric material, such as an oxide. The insulating layer 116 provides electrical insulation between the interconnects 118 and the electrodes 110 not connected to them. In other embodiments, the horizontal sections of the electrodes 110 that extend in the X-direction on the top surface 102 of the semiconductor structure 100 may be positioned between the interconnects 118 and the insulating layer 114, as illustrated in FIG. 4. That is, the interconnects 118 may be disposed over the electrodes 110 on the top surface 102 of the semiconductor structure 100. In these embodiments, the insulating layer 116 is located over the electrodes 110 between the interconnects 118 and the electrodes 110.

The electrically isolated electrodes 110 are made of silicon-based conductive material, e.g., doped polysilicon, having etch selectivity with respect to a masking layer, e.g., a photoresist layer, and the insulating layer 114 for deep reactive ion etching (DRIE). Thus, the etching rate of the silicon-based conductive material is significantly greater than those of the masking layer and the insulating layer 114. The silicon-based conductive material allows the vertical sections of the electrodes 110 that extend in the Y-direction to be defined by etching a layer of the silicon-based conductive material that has been deposited over the semiconductor core 112 to cover the insulating layer 114, the interconnects 118 and the insulating layer 116. In one embodiment, the electrodes 110 are formed using a stop-on-oxide DRIE, as described in U.S. Pat. No. 6,187,685 to Hopkins et al. entitled “Method and Apparatus for Etching a Substrate”, which is incorporated herein by reference. This process allows a silicon-based conductive material to be anisotropically etched with minimal undercutting to form substantially vertical surfaces of the electrodes at the side surfaces 106 and 108 of the semiconductor structure 100. Etching the silicon-based conductive material, e.g., the doped polysilicon, results in thin strips of conductive material that vertically extend in a direction orthogonal to the top surface of the semiconductor core 112 along the side surfaces 106 and 108 of the semiconductor structure 100 and horizontally extend in a direction parallel to the top surface of the semiconductor core 112 along the top surface 102 of the structure, as shown in FIGS. 1, 2 and 3.

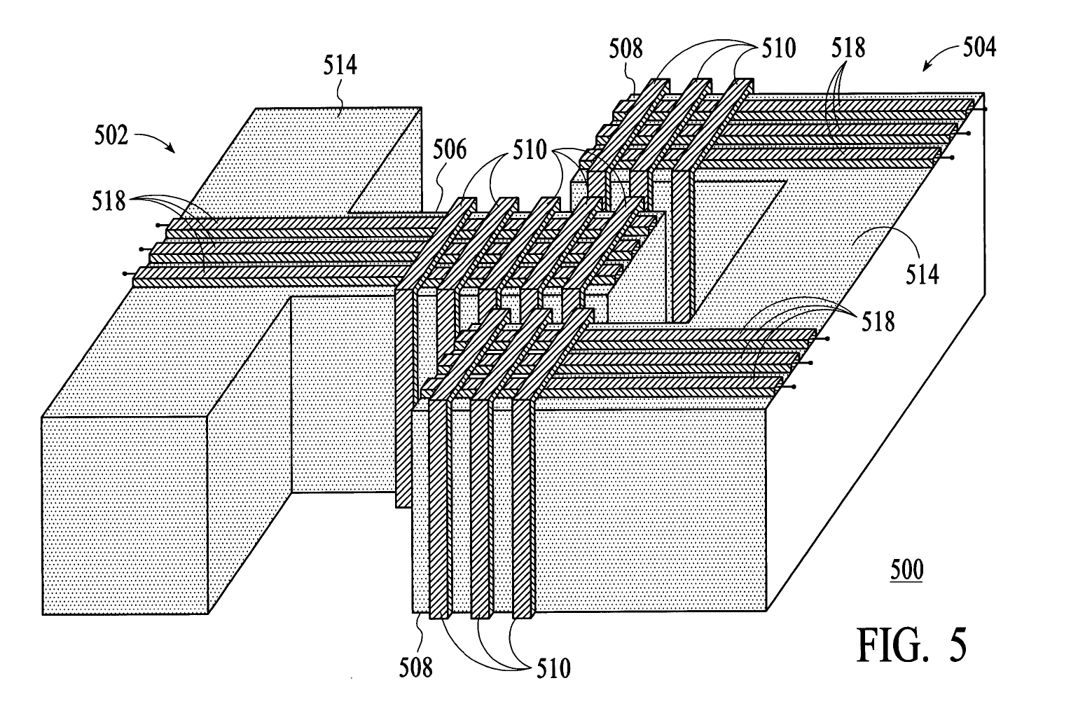

As previously stated, the semiconductor structure 100 may be used as a component of a MEMS device. As an example, the semiconductor structure 100 may be configured as a movable member (“mover”) or a stationary member (“stator”) of an electrostatic actuator that is described in a simultaneously filed U.S. patent application Ser. No. XX/XXX,XXX entitled “Stepping Electrostatic Comb Drive Actuator”, which is assigned to the same assignee of this disclosure, and is specifically incorporated by reference herein. A portion of a similar electrostatic actuator 500 is illustrated in FIG. 5. The electrostatic actuator 500 includes a movable semiconductor structure (“mover”) 502 and a stationary semiconductor structure (“stator”) 504. The portion of the movable semiconductor structure 502 shown includes a mover finger 506, while the portion of the stationary semiconductor structure 504 shown includes two stator fingers 508. Typically, the movable and stationary semiconductor structures 502 and 504 include many additional interdigitated mover and stator fingers, respectively. Similar to the semiconductor structure 100, each of the mover and stator fingers 506 and 508 has electrically isolated electrodes 510 and interconnects 518, which are connected to selected areas of the electrodes. In addition, each of the mover and stator fingers 506 and 508 includes a first insulating layer 514, which is located below the interconnects 518, and a second insulating layer (not shown), which is located between the interconnects 518 and the electrodes 510. Although, the mover finger 506 is shown to have five electrodes 510 and each stator finger 508 is shown to have three electrodes 510, the mover and stator fingers typically have many more electrodes. The mover and stator fingers 506 and 508 are interdigitated such that the electrodes 510 on the sides the mover finger oppose the electrodes 510 on the sides of the stator fingers. Many movable and stationary semiconductor structures 502 and 504 may be fabricated from a single silicon wafer by a wafer fabrication process similar to the fabrication process of the semiconductor structure 100, as described above.

The operation of the electrostatic actuator 500 involves selectively applying voltages to the interconnects 518 of the movable and stationary semiconductor structures 502 and 504. The applied voltages on the interconnects 518 create lateral electrostatic forces between electrodes 510 of the mover finger 506 and the electrodes 510 of the stator fingers 508, which cause the movable semiconductor structure 502 to be displaced relative to the stationary semiconductor structure 504, as described in the simultaneously filed U.S. patent application entitled “Stepping Electrostatic Comb Drive Actuator”.

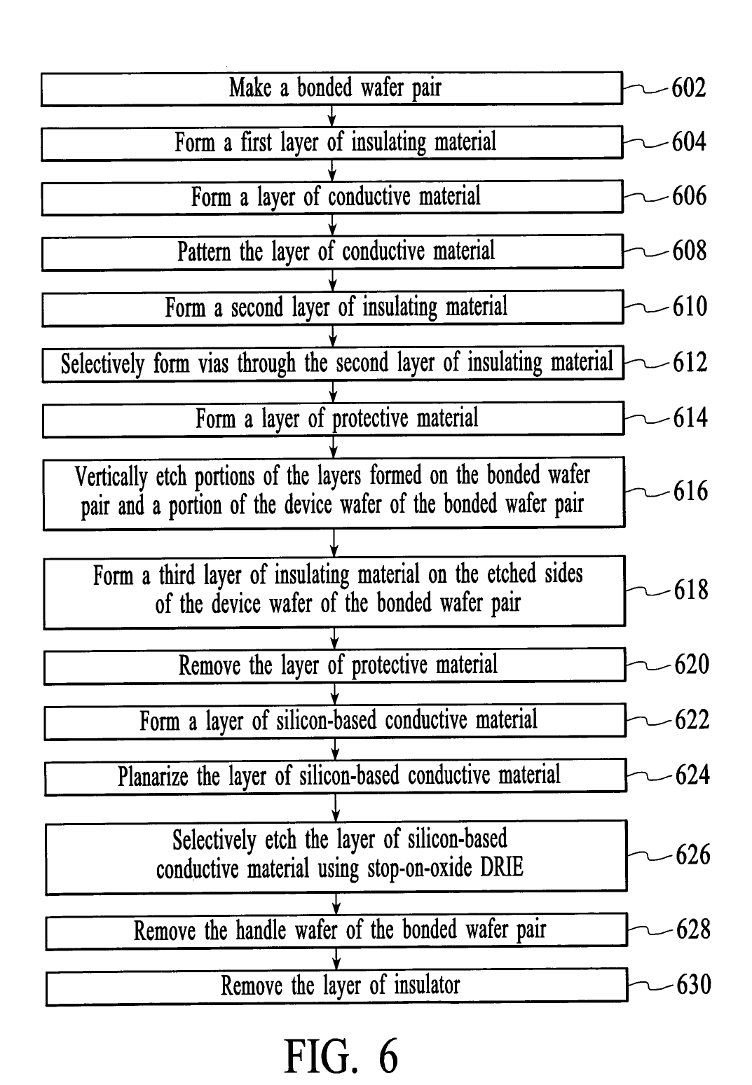

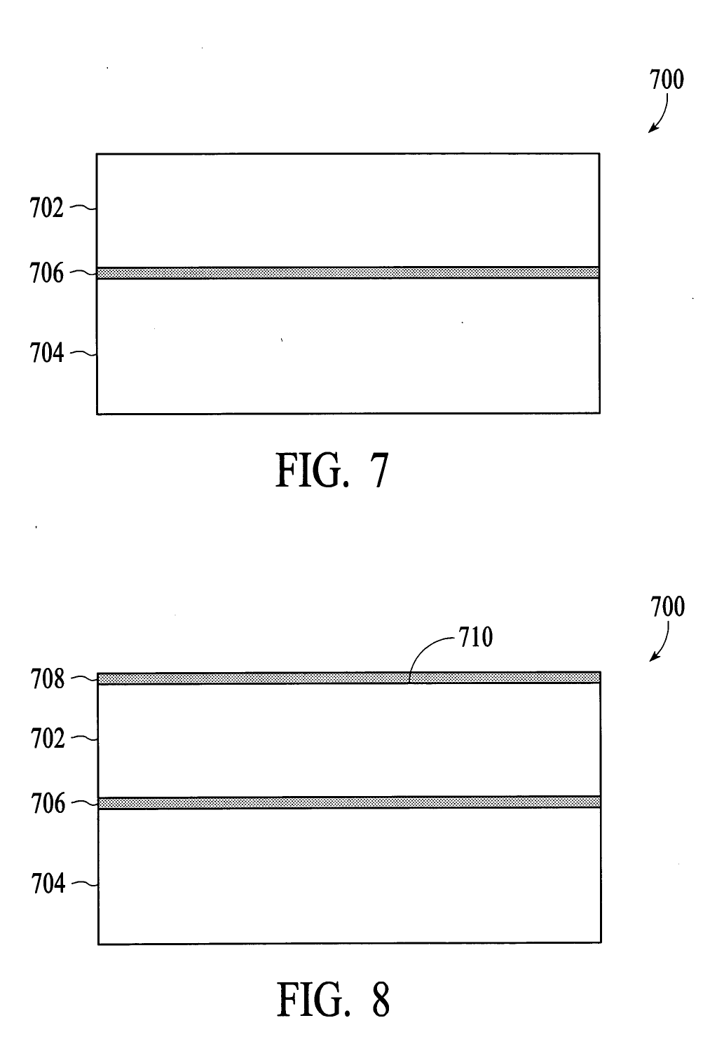

A process for fabricating the semiconductor structure 100 in accordance with an embodiment of the invention is now described with reference to a flow diagram of FIG. 6 and illustrations of FIGS. 7-22. At block 602, a bonded wafer pair 700 is made, as illustrated in FIG. 7. In FIGS. 7-22, only a small portion of the bonded wafer pair 700 that will be used to fabricate the semiconductor structure 100 is shown. The bonded wafer pair 700 includes a silicon device wafer 702 and a silicon handle wafer 704, which are attached by a layer 706 of insulator. The layer 706 of insulator may be a layer of thermal oxide. As described in more detail below, the device wafer 702 will become the semiconductor core 112 of the semiconductor structure 100.

Next, at block 604, a first layer 708 of insulating material is formed on the bonded wafer pair 700, as illustrated in FIG. 8. The first layer 708 of insulating material will become a part of the insulating layer 114 of the semiconductor structure 100 that is located on the top surface of the semiconductor core 112. The insulating material may be a thermal oxide, which is grown on the major surface 710 of the bonded wafer pair 700.

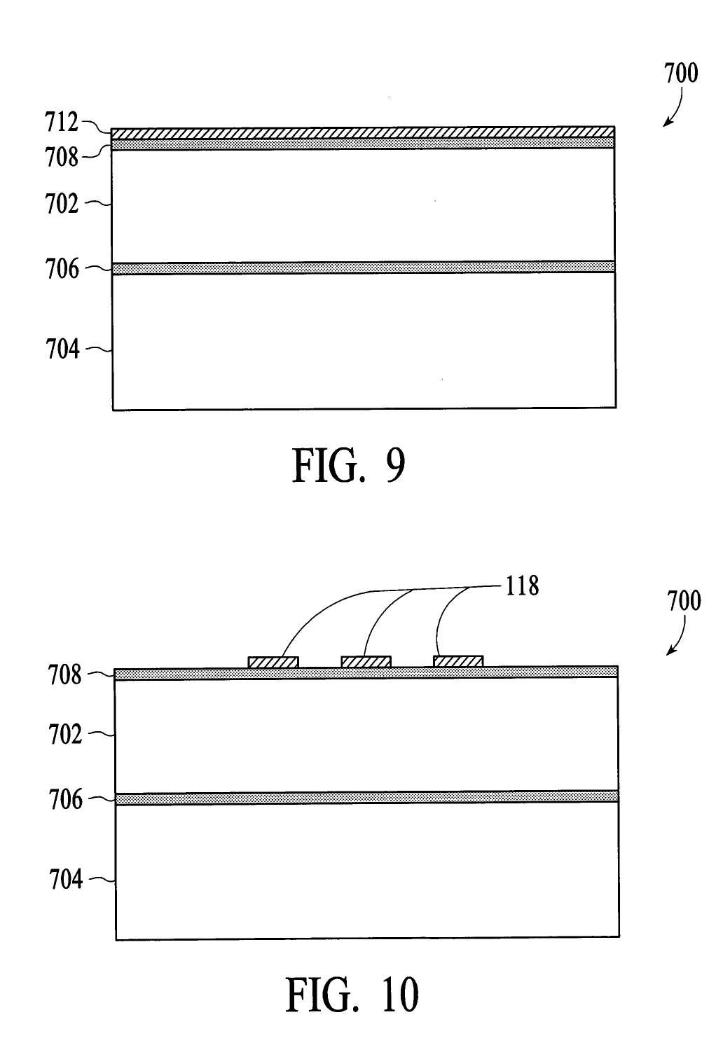

At block 606, a layer 712 of conductive material, e.g., polysilicon, is formed on the layer 708 of insulating material, as illustrated in FIG. 9. As an example, the layer 712 of conductive material may be formed by first depositing undoped polysilicon onto the layer 708 of insulating material. The polysilicon is then implanted with phosphorus ions to make it conductive.

Next, at block 608, the layer 712 of conductive material is patterned to define the interconnects 118 of the semiconductor structure 100 in the layer of conductive material using a masking layer (not shown), e.g., a photoresist layer, to protect the areas of the layer of conductive material not to be etched, as illustrated in FIG. 10.

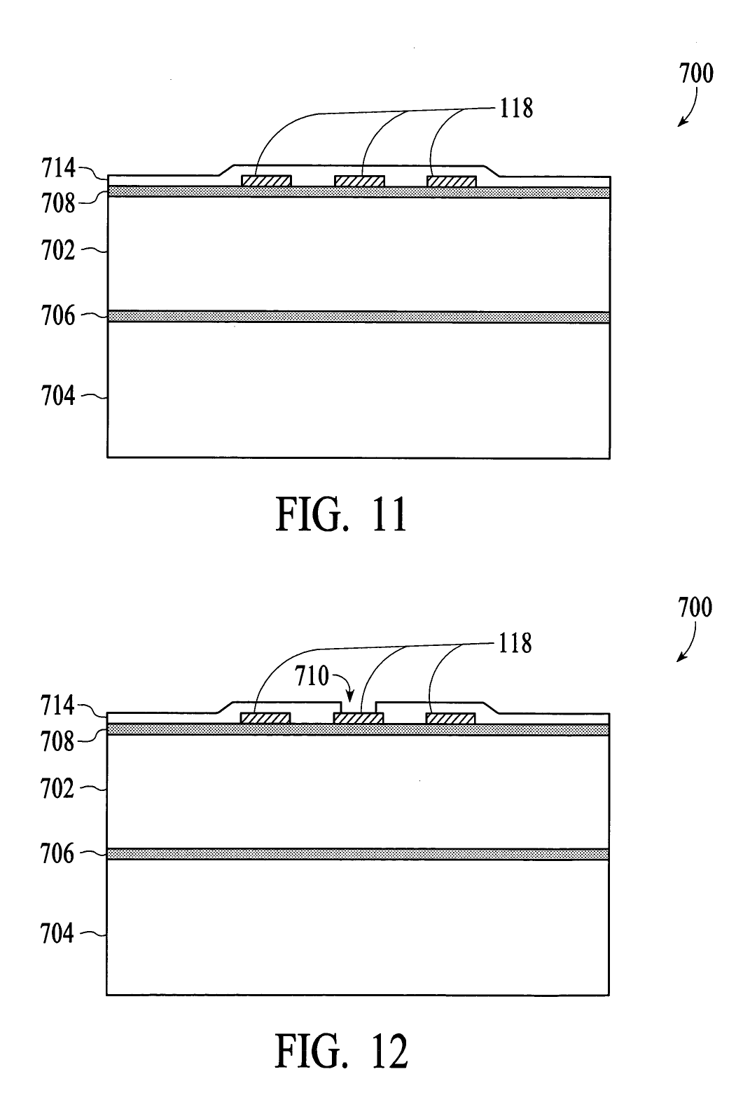

Next, at block 610, a second layer 714 of insulating material is formed on the interconnects 118 and exposed portions of the underlying first layer 708 of insulating material, as illustrated in FIG. 11. The second layer 714 of insulating material may be formed of a low-pressure chemical-vapor-deposited is (LPCVD) oxide, which is deposited on the surfaces of the interconnects 118 and the exposed portions of the layer 708 of insulating material. The second layer 714 of insulating material will become the insulating layer 116 of the semiconductor structure 100.

At block 612, vias 716 are selectively formed through the second layer 714 of insulating material, as illustrated in FIG. 12, so that the interconnects 118 will be selectively and electrically connected to the electrodes 110 when the electrodes are later formed over the second layer of insulating material. The vias 716 can be formed by selectively etching through the second layer 714 of insulating material to define the vias in the second layer using a masking layer (not shown), e.g., a photoresist layer, to protect the areas of the second layer not to be etched.

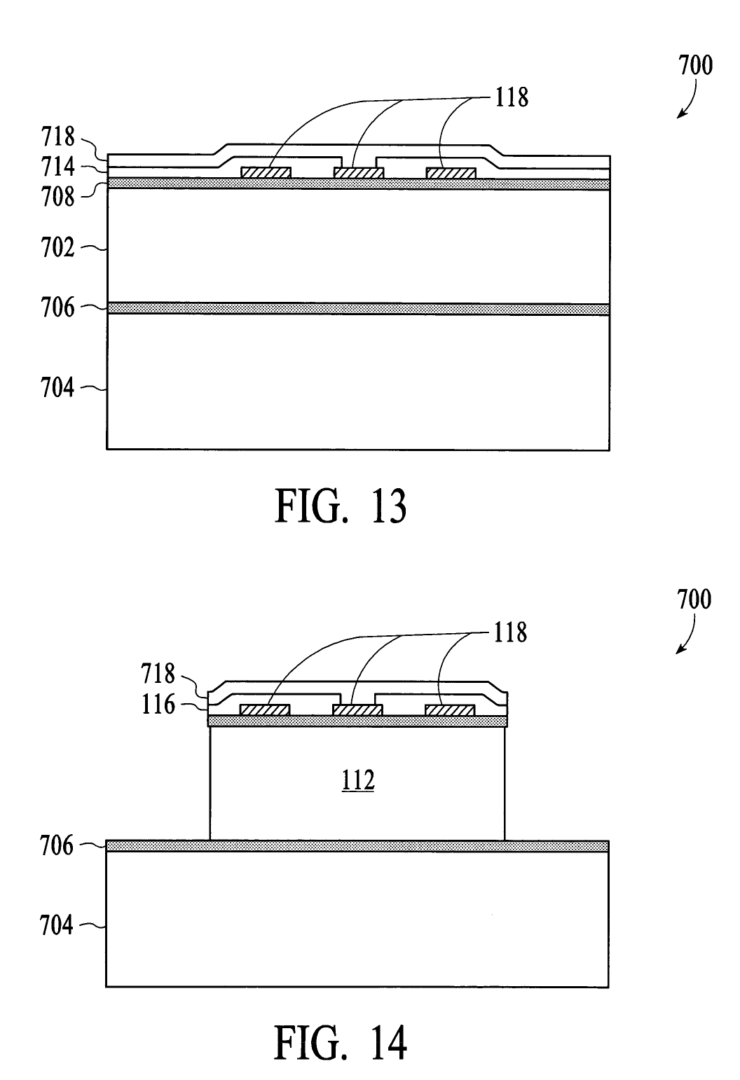

Next, at block 614, a layer 718 of protective material, e.g., silicon nitride, is formed over the second layer 714 of insulating material, as illustrated in FIG. 13. The layer 718 of protective material is used to prevent exposed portions of the interconnects 118, i.e., the portions of the interconnects exposed by the vias 716, from being oxidized during subsequent processing steps.

At block 616, portions of the layers 708, 714 and 718 formed on the bonded wafer pair 700 and a portion of the device wafer 702 of the bonded wafer pair are vertically etched down to the layer 706 of insulator using a masking layer (not shown), e.g., a photoresist layer, to protect the areas not to be etched. As an example, the portions of the layers 708, 714 and 718 and the portion of the device wafer 702 may be etched using DRIE. Consequently, the semiconductor core 112, part of the insulating layer 114 and the insulating layer 116 of the semiconductor structure 100 are defined, as illustrated in FIG. 14.

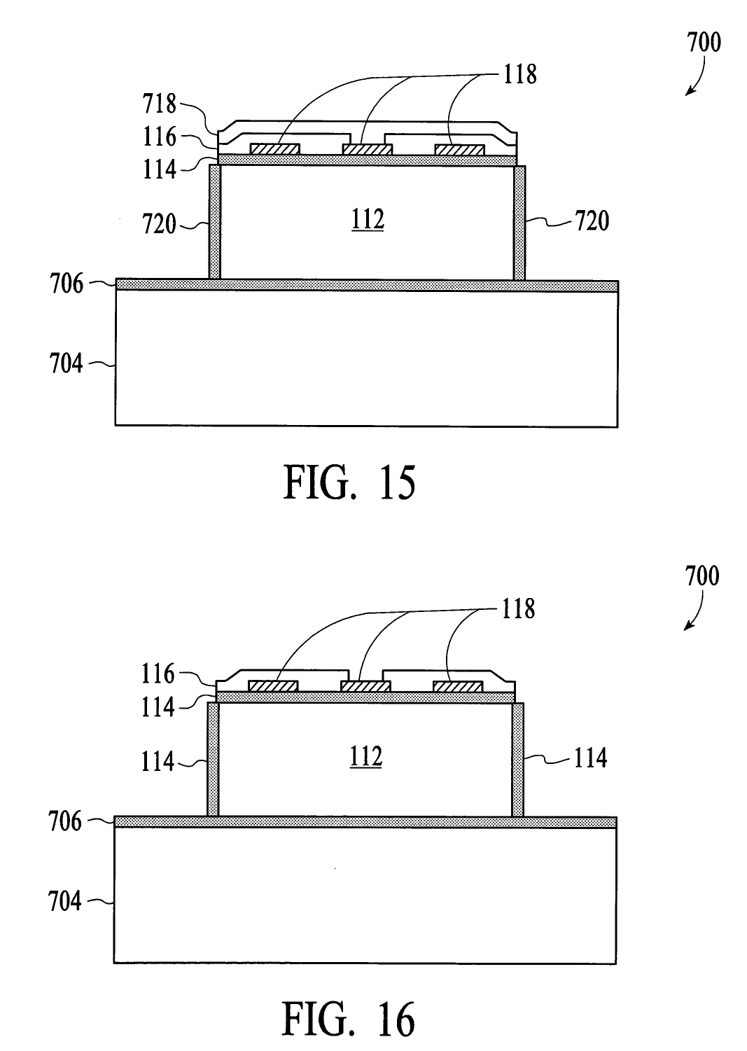

Next, at block 618, a third layer 720 of insulating material is formed on the etched sides of device wafer 702 of the bonded wafer pair 700, as illustrated in FIG. 15. The device wafer 702 is shown in FIG. 15 as the semiconductor core 112 since the semiconductor core has now been defined from the device wafer. The insulating material of the third layer 720 may also be a thermal oxide, which is grown on the etched sides of the semiconductor core 112. The third layer 720 of the insulating material forms the remaining portion of the insulating layer 114 of the semiconductor structure 100.

At block 620, the layer 718 of protective material is removed, as illustrated in FIG. 16. As an example, if the protective material is silicon nitride, the protective layer 718 may be stripped using heated phosphoric acid.

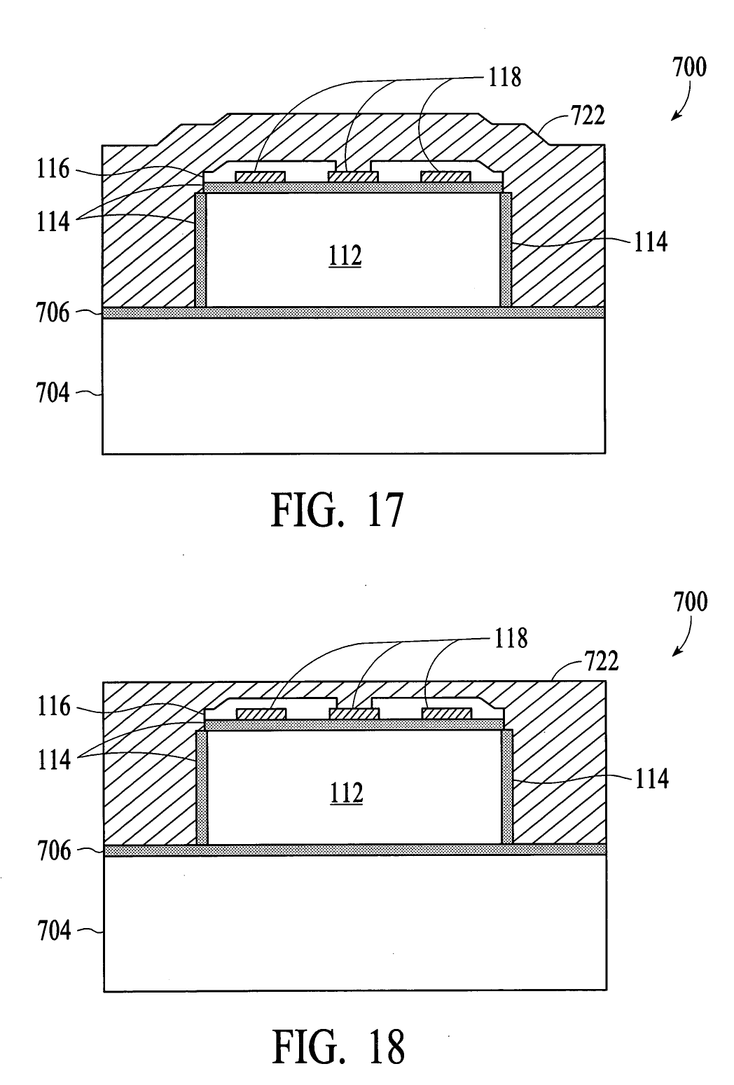

Next, at block 622, a layer 722 of silicon-based conductive material, e.g., doped polysilicon, is formed on the insulating layer 116, the exposed portions of the interconnects 118, and exposed portions of the layer 706 of insulator, as illustrated in FIG. 17.

At block 624, the layer 722 of silicon-based conductive material is then planarized by, for example, chemical-mechanical planarization (CMP), as illustrated in FIG. 18.

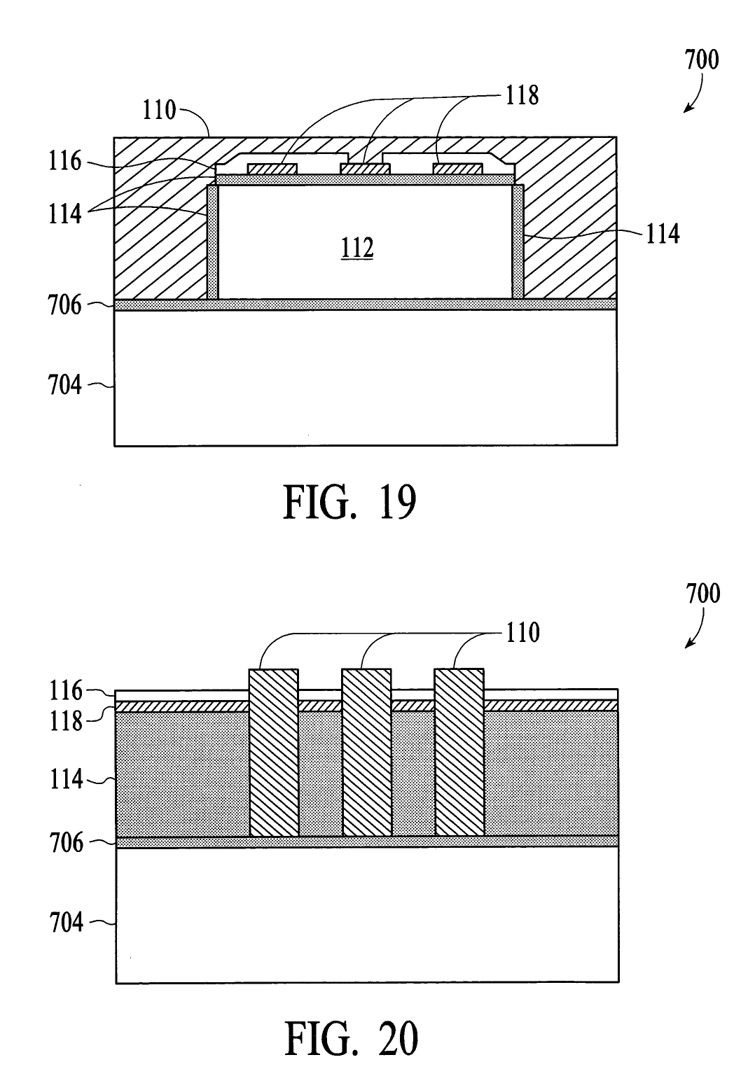

Next, at block 626, the planarized layer 722 of silicon-based conductive material is selectively and anisotropically etched down to the layer 706 of insulator to define the electrically isolated electrodes 110 in the planarized layer using a masking layer (not shown), e.g., a photoresist layer, to protect the areas of the planarized layer not the be etched, as illustrated in FIGS. 19 and 20. FIG. 20 shows a side view of the electrically isolated electrodes 110. The layer 722 of silicon-based conductive material is etched using a stop-on-oxide DRIE, which is an etching process that selectively etches a target material until oxide is reached. Thus, with respect to the layer 722 of silicon-based conductive material, the DRIE etching stops at the insulating layers 114 and 116, and the layer 706 of insulator.

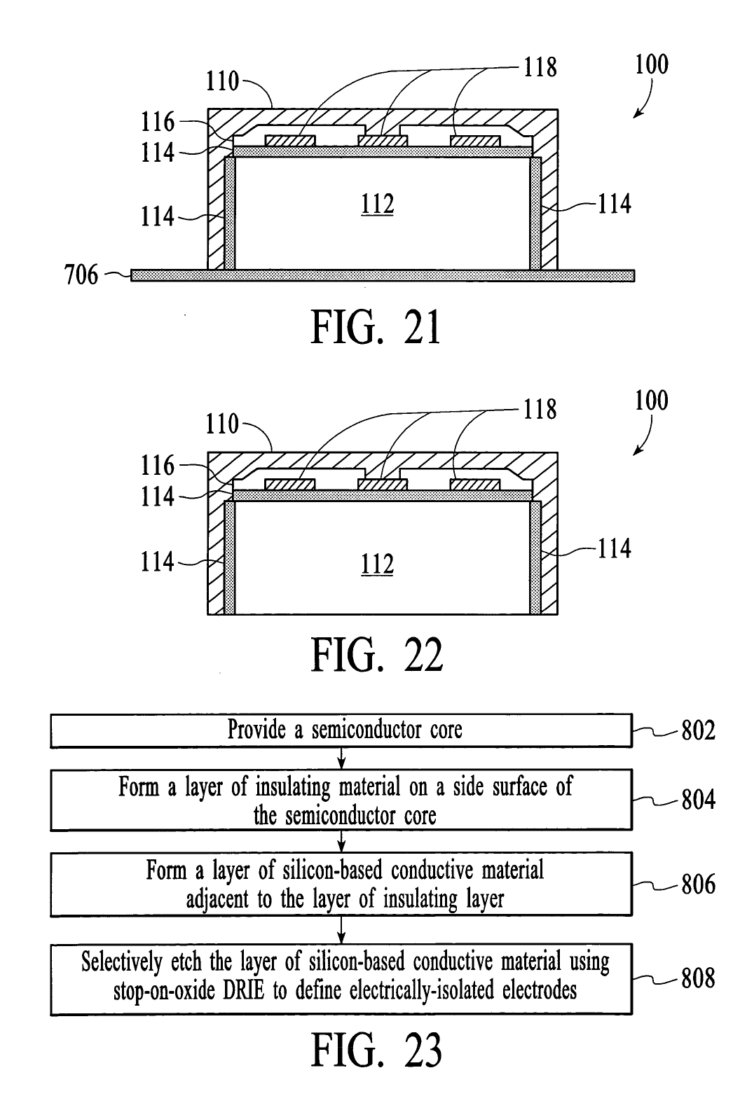

At block 628, the handle wafer 704 of the bonded wafer pair 700 is removed using, for example, DRIE, as illustrated in FIG. 21. Next, at block 630, the layer 706 of insulator is removed using, for example, buffered hydrofluoric acid (BHF), as illustrated in FIG. 22, which completes the fabrication process of the semiconductor structure 100.

A method for fabricating a semiconductor structure with electrically isolated sidewall electrodes in accordance with an embodiment of the invention is now described with reference to a flow diagram of FIG. 23. At block 802, a semiconductor core is provided. The semiconductor core may be a single-crystal silicon core, which may be derived from a bonded wafer pair. Next, at block 804, a layer of insulating material is formed on a side surface of the semiconductor core. The insulating material may be thermal oxide. At block 806, a layer of silicon-based conductive material is then formed adjacent to the layer of insulating material. The silicon-based conductive material may be doped polysilicon. Next, at block 808, the layer of silicon-based conductive material is selectively etched using a stop-on-oxide DRIE to define the electrically isolated electrodes in the layer of silicon-based conductive material such that the electrically isolated electrodes are arrayed along the layer of insulating material on the side surface of the semiconductor core.

Although specific embodiments of the invention have been described and illustrated, the invention is not to be limited to the specific forms or arrangements of parts so described and illustrated. The scope of the invention is to be defined by the claims appended hereto and their equivalents.

1. A semiconductor structure comprising:
a semiconductor core having a side surface;
a layer of insulating material on said side surface; and
electrically isolated electrodes arrayed along said layer of insulating material on said side surface, said electrically isolated electrodes including a conductive material having etch selectivity with respect to said insulating material.

2. The semiconductor structure of claim 1 wherein said electrically isolated electrodes extend substantially in a direction orthogonal to a major surface of said semiconductor core, said major surface being orthogonal to said side surface.

3. The semiconductor structure of claim 1 wherein said conductive material includes silicon-based conductive material.

4. The semiconductor structure of claim 3 wherein said silicon-based conductive material includes polysilicon.

5. The semiconductor structure of claim 1 wherein said semiconductor core includes single-crystal silicon.

6. The semiconductor structure of claim 1 wherein said insulating material of said layer includes oxide of said semiconductor core.

7. The semiconductor structure of claim 1 wherein said electrically isolated electrodes are additionally arrayed over a major surface of said semiconductor core, said major surface being orthogonal to said side surface.

8. The semiconductor structure of claim 7 further comprising interconnects electrically connected to selected ones of said electrically isolated electrodes, said interconnects being positioned over said major surface of said semiconductor core.

9. The semiconductor structure of claim 7 wherein said electrically isolated electrodes are additionally arrayed along a second side surface of said semiconductor core.

10. A semiconductor structure comprising:
a semiconductor core having a major surface and a side surface, said major surface being orthogonal to said side surface;
a layer of insulating material on said side surface; and
electrically isolated electrodes arrayed along said layer of insulating material on said side surface such that said electrically isolated electrodes extend substantially in a direction orthogonal to said major surface, said electrically isolated electrodes including conductive material having etch selectivity with respect to said insulating material.

11. The semiconductor structure of claim 10 wherein said conductive material includes silicon-based conductive material.

12. The semiconductor structure of claim 11 wherein silicon-based conductive material includes doped polysilicon.

13. The semiconductor structure of claim 10 wherein said semiconductor core includes single-crystal silicon.

14. The semiconductor structure of claim 10 wherein said electrically isolated electrodes additionally extend over said major surface of said semiconductor core.

15. The semiconductor structure of claim 14 further comprising interconnects electrically connected to selected ones of said electrically isolated electrodes, said interconnects being positioned over said major surface of said semiconductor core.

16. A method for fabricating a semiconductor structure, the method comprising:
providing a semiconductor core with a side surface;
forming a layer of insulating material on said side surface of said semiconductor core;
forming a layer of conductive material adjacent to said layer of insulating material on said side surface, said conductive material having etch selectively with respect to said insulating material; and
selectively etching said layer of conductive material using a stop-on-oxide deep reactive ion etching to define electrically isolated electrodes arrayed along said layer of insulating material on said side surface.

17. The method of claim 16 wherein said selectively etching includes selectively etching said layer of conductive material using said stop-on-oxide deep reactive ion etching such that said electrical isolated electrodes extend substantially in a direction orthogonal to a major surface of said semiconductor core, said major surface being orthogonal to said side surface.

18. The method of claim 16 wherein said forming of said layer insulating material includes forming a layer of oxide on said side surface of said semiconductor core.

19. The method of claim 16 wherein said forming of said layer of conductive material includes forming a layer of silicon-based conductive material adjacent to said layer of insulating material.

20. The method of claim 19 wherein said forming of said layer of silicon-based conductive material includes forming a layer of polysilicon adjacent to said layer of insulating material.

21. The method of claim 16 wherein said providing of said semiconductor core includes providing a single-crystal silicon core with said side surface.

22. The method of claim 16 wherein said forming of said layer of conductive material includes forming said layer of conductive material over a major surface of said semiconductor core, said major surface being orthogonal to said side surface, and wherein said selectively etching of said layer of conductive material includes selectively etching said layer of conductive material over said major surface of said semiconductor core using said stop-on-oxide deep reactive ion etching such that said electrically isolated electrodes extend over said major surface of said semiconductor core.

23. The method of claim 22 further comprising forming interconnects over said major surface of said semiconductor core, said interconnects being electrically connected to selected ones of said electrically isolated electrodes.
